(19) United States
(12) Patent Application Publication
(10) Pub. No.: US 2019/0305195 A1
(43) Pub. Date: Oct. 3, 2019

(54) WAVELENGTH CONVERSION MEMBER AND LIGHT EMITTING DEVICE

(71) Applicant: Sharp Kabushiki Kaisha, Osaka (JP)

(72) Inventors: Hiroshi FUKUNAGA, Sakai City (JP); Tatsuya RYOHWA, Sakai City (JP); Kanako NAKATA, Sakai City (JP); Kenichi YOSHIMURA, Sakai City (JP); Masatsugu MASUDA, Sakai City (JP)

(21) Appl. No.: 16/362,773

(22) Filed: Mar. 25, 2019

(30) Foreign Application Priority Data
Apr. 2, 2018 (JP) 2018-070860
Apr. 4, 2018 (JP) 2018-072608

(51) Int. Cl. H01L 33/50; H01L 33/54; C09K 11/02

(52) U.S. Cl. CPC H01L 33/507; C09K 11/025; H01L 33/54; H01L 33/502

(57) ABSTRACT

The present invention facilitates production of a wavelength conversion member which is produced with use of a phosphor element containing a semiconductor nanoparticle phosphor. A phosphor element (10) includes semiconductor nanoparticle phosphors (11) dispersed in a matrix (12). An encapsulation body (13) has a thickness L and an inner diameter R which have therebetween a ratio of not more than 1, the phosphor element (10) has a particle size of 1 μm to 30 μm, and the phosphor element (10) is sealed in the wavelength conversion member while having a weight of not more than 0.8 g with respect to 1 g of a sealing material.

This Nonprovisional application claims priority under 35 U.S.C. § 119 on (i) Patent Application No. 2018-070860 filed in Japan on Apr. 2, 2018 and (ii) Patent Application No. 2018-072608 filed in Japan on Apr. 4, 2018, the entire contents of which are hereby incorporated by reference.

### TECHNICAL FIELD

The present disclosure relates to (i) a wavelength conversion member containing a semiconductor nanoparticle phosphor and (ii) a light emitting device.

### BACKGROUND ART

Semiconductor nanoparticles, whose use as phosphors are attracting attention, are being studied. Semiconductor nanoparticle phosphors may be used as a phosphor element by being dispersed in a matrix and encapsulated in an encapsulation body. Patent Document 1 discloses primary particles (a phosphor element) including a group of semiconductor nanoparticles. The primary particles are each provided with a layer made of a surface coating material.

### CITATION LIST

### Patent Literature

[Patent Literature 1]

Japanese Translation of PCT International Application, Tokuhyo, No. 2013-505347 (Publication Date: Feb. 14, 2013)

### SUMMARY OF INVENTION

### Technical Problem

During production of a wavelength conversion member including a phosphor element, the phosphor element is ordinarily sealed with a sealing material.

Note, however, that the inventors of the present invention have found that an increase in amount in which to add a phosphor element to a certain amount of a sealing material hinders production of a wavelength conversion member.

An aspect of the present disclosure has an object to achieve (i) a phosphor element that facilitates production of a wavelength conversion member which is produced with use of the phosphor element containing a semiconductor nanoparticle phosphor and (ii) a wavelength conversion member including the phosphor element.

### Solution to Problem

In order to attain the object, a wavelength conversion member in accordance with the present disclosure includes: a phosphor element; and a sealing material in which to seal the phosphor element, the phosphor element including: an encapsulation body which defines an encapsulation space and is hollow and light-transmissive; a matrix which is encapsulated in the encapsulation body and contains (i) an ionic liquid or (ii) a resin having a structural unit derived from the ionic liquid; and semiconductor nanoparticle phosphors dispersed in the matrix, the encapsulation body having a thickness L and an inner diameter R which have therebetween a ratio L/R of not more than 1, the phosphor element having a particle size of not less than 1 μm and not more than 30 μm, and the phosphor element being sealed in the wavelength conversion member while having a weight of not more than 0.8 g with respect to 1 g of the sealing material.

### Advantageous Effects of Invention

An aspect of the present disclosure makes it possible to facilitate production of a wavelength conversion member which is produced with use of a phosphor element containing a semiconductor nanoparticle phosphor.

### BRIEF DESCRIPTION OF DRAWINGS

FIG. 1 is a perspective view illustrating a configuration of a wavelength conversion member in accordance with Embodiment 1.

FIG. 2 is a cross-sectional view illustrating a configuration of a phosphor element.

FIG. 3 is a perspective view illustrating a configuration of a wavelength conversion member in accordance with Embodiment 2.

FIG. 4 is a cross-sectional view illustrating a configuration of a phosphor element in accordance with Embodiment 3.

FIG. 5 is a cross-sectional view illustrating a configuration of a phosphor element in accordance with Embodiment 4.

FIG. 6 is a cross-sectional view illustrating a configuration of an LED package in accordance with Embodiment 5.

FIG. 7 is a cross-sectional view illustrating a configuration of an LED package including phosphor elements and conventional phosphors.

FIG. 8 is a cross-sectional view illustrating a configuration of an LED package in accordance with Embodiment 6.

FIG. 9 is a cross-sectional view illustrating a configuration of an LED package in accordance with Embodiment 7.

FIG. 10 is a cross-sectional view illustrating a configuration of an LED package in accordance with Embodiment 8.

FIG. 11 is a cross-sectional view illustrating a configuration of an LED package in accordance with Embodiment 9.

FIG. 12 shows test results obtained in Example 1.

FIG. 13 is an electron micrograph showing a cross section of an encapsulation body which is spherical and has fine pores each extending from a surface toward an inside of the encapsulation body.

FIG. 14 is an electron micrograph showing a cross section of an encapsulation body whose L/ R is more than 1.

FIG. 15 has cross-sectional views illustrating a respective plurality of types of LED packages used in Example 2.

FIG. 16 shows results of a test for LED packages which are caused to illuminate.

### DESCRIPTION OF EMBODIMENTS

### Embodiment 1

The following description will specifically discuss an embodiment of the present disclosure. The following description assumes that in the drawings of the present application, identical reference signs denote respective identical or equivalent parts. Furthermore, dimensions such as a length, a size, and a width in the drawings are appropriately altered so that the drawings will be made clear and simple, and the dimensions are not actual dimensions.

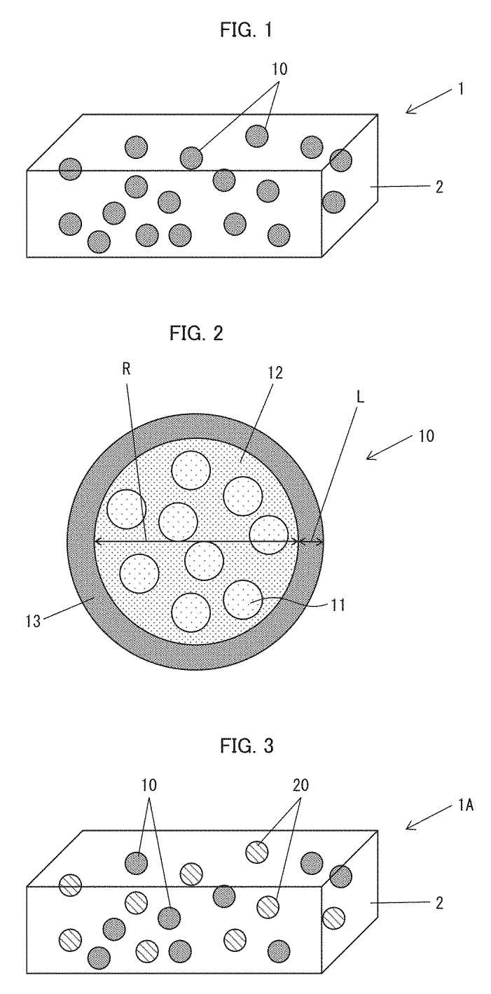

FIG. 1 is a perspective view illustrating a configuration of a wavelength conversion member 1 in accordance with Embodiment 1. As illustrated in FIG. 1, the wavelength conversion member 1 includes phosphor elements 10 (primary particles) and a sealing material 2 in which to seal the phosphor elements 10.

The sealing material 2 is an optically transparent dispersion medium and is made of, for example, a resin. Specifically, the sealing material 2 is made of a polymer, epoxy, silicone (meth)acrylate, silica glass, silica gel, siloxane, sol-gel, hydrogel, agarose, cellulose, epoxy, polyether, polyethylene, polyvinyl, polydiacetylene, polyphenylenevinylene, polystyrene, polypyrrole, polyimide, polyimidazole, polysulfone, polythiophene, polyphosphate, poly(meth)acrylate, polyacrylamide, polypeptide, polysaccharide, or a combination thereof.

FIG. 2 is a cross-sectional view illustrating a configuration of each of the phosphor elements 10. As illustrated in FIG. 2, the phosphor elements 10 each include an encapsulation body 13, a matrix 12 encapsulated in the encapsulation body 13, and semiconductor nanoparticle phosphors 11 dispersed in the matrix 12. The matrix 12 contains an ionic liquid or a structural unit derived from the ionic liquid.

The phosphor elements 10 can have any shape that is not limited to a spherical shape. The phosphor elements 10 can have a shape (e.g., a cube) having a polygonal cross-sectional shape. The phosphor elements 10 preferably have a particle size (diameter) of not less than 1 μm and not more than 30 μm. The phosphor elements 10 which have a particle size of not more than 30 μm tends to be made dispersible in the sealing material 2 by a process similar to a process by which to disperse conventional phosphors in the sealing material 2. The phosphor elements 10 which have a smaller particle size are easier to handle in the sealing material 2. Meanwhile, the phosphor elements 10 which have a particle size of more than 30 μm may cause clogging in a dispenser while being dispersed in the sealing material 2 so as to be applied to an application target. This may result in a lower yield during production.

Note, however, that the phosphor elements 10 which have a too small particle size cause a reduction in amount in which a single phosphor element 10 is to hold therein the matrix 12 and the semiconductor nanoparticle phosphors 11. This consequently necessitates many phosphor elements 10. The phosphor elements 10 which have a large particle size allow a single phosphor element 10 to hold therein a large amount of the matrix 12 and many semiconductor nanoparticle phosphors 11. In view of this, the phosphor elements 10 preferably have a particle size of not less than 1 μm.

In view of the above-described advantages and disadvantages for each particle size, a largest diameter of the phosphor elements 10 which are aspherical and are strained or have a polygonal cross-sectional shape is regarded as a particle size of the phosphor elements 10.

A semiconductor nanoparticle phosphor 11 is a nanosized phosphor particle and is a single phosphor particle in which no scattering of visible light occurs. The semiconductor nanoparticle phosphor 11 is composed of one or more kinds of semiconductor crystals.

The semiconductor nanoparticle phosphor 11 has a particle size (diameter) which can be appropriately selected in accordance with a material and a desired emission wavelength and which is not limited to any particular size. The semiconductor nanoparticle phosphor 11 has a particle size which falls within the range of, for example, 1 nm to 20 nm.

The semiconductor nanoparticle phosphor 11 preferably contains a semiconductor nanoparticle which is one or more semiconductor materials selected from the group consisting of CdS, CdSe, CdTe, ZnS, ZnSe, ZnTe, InN, InP, InAs, InSb, AlP, A1S, AlAs, AlSb, GaN, GaP, GaAs, GaSb, PbS, PbSe, Si, Ge, MgS, MgSe, MgTe, and a combination thereof.

Furthermore, the semiconductor nanoparticle phosphor 11 can be any of a two-component core type nanoparticle, a three-component core type nanoparticle, a four-component core type nanoparticle, a core-shell type or core-multishell type nanoparticle, a doped nanoparticle, and an inclined nanoparticle each of which is known to a person skilled in the art.

The semiconductor nanoparticle phosphor 11 has a modified organic group on a surface thereof. This makes it possible to prevent agglomeration of semiconductor nanoparticle phosphors 11. Furthermore, the semiconductor nanoparticle phosphors 11, whose surfaces are polar, can be satisfactorily dispersed in a matrix containing a structural unit derived from an ionic liquid. This makes it possible to restrain the semiconductor nanoparticle phosphors 11 from deteriorating due to agglomeration thereof.

The matrix 12 is a dispersion medium by which to stably disperse semiconductor nanoparticle phosphors and contains an ionic liquid or a structural unit derived from the ionic liquid. The term “ionic liquid” herein means a salt (ambient temperature molten salt) in a molten state even at a room temperature (e.g., 25° C.) and is represented by the following general formula (1).

X⁺Y⁻ (1)

In the above general formula (1), X⁺ is a cation selected from imidazolium ion, pyridinium ion, phosphonium ion, aliphatic quaternary ammonium ion, pyrrolidinium, and sulfonium. Among these cations, aliphatic quaternary ammonium ion is particularly preferable because the aliphatic quaternary ammonium ion has excellent thermal stability and excellent atmospheric stability.

In the above general formula (1), Y⁻ is an anion selected from tetrafluoroborate ion, hexafluorophosphate ion, bistrifluromethylsulfonylimidate ion, perchlorate ion, tris(trifluoromethylsulfonyl)carbonate ion, trifluoromethanesulfonate ion, trifluoroacetate ion, carboxylate ion, and halogen ion. Among these anions, bistrilfuloromethylsulfonylimidate ion is particularly preferable because the bistrilfuloromethylsulfonylimidate ion has excellent thermal stability and excellent atmospheric stability.

For example, the matrix 12 contains, as a main component (e.g., in an amount of not less than 80% by mass), a resin containing a structural unit derived from an ionic liquid having a polymerizable functional group. Examples of the ionic liquid having a polymerizable functional group include 2-(methacryloyloxy)-ethyltrimethylammonium bis(trifluoromethanesulfonyl)imide and 1-(3-acryloyloxy-propyl-3-methylimidazolium bis(trifluoromethanesulfonyl)imide.

Furthermore, the matrix 12 can contain, as a main component (e.g., in an amount of not less than 80% by mass), a resin containing a structural unit derived from an ionic liquid having no polymerizable functional group. Examples of the ionic liquid having no polymerizable functional group include N,N,N-trimethyl-N-propylammonium bis(trifluoromethanesulfonyl)imide and N,N-dimethyl-N-methyl-2-(2-methoxyethyl)ammonium bis(trifluoromethanesulfonyl)imide.

The resin containing a structural unit derived from an ionic liquid can be formed by, for example, thermally-curing or photo-curing the ionic liquid with use of a cross-linking agent. The ionic liquid can be cured by (i) a photocuring method in which the ionic liquid is cured by being irradiated with ultraviolet rays or (ii) a thermal curing method in which the ionic liquid is cured by applying heat thereto.

Such a substance described above and serving as the matrix 12 has no vapor pressure and hardly vaporizes, so that the substance can maintain its stable state. Furthermore, the substance has an effect of electrostatically stabilizing the surfaces of the semiconductor nanoparticle phosphors 11 so that the semiconductor nanoparticle phosphors 11 are stably dispersed without being agglomerated. This makes it possible to maintain high efficiency with which to emit light.

The encapsulation body 13 is a hollow and light-transmissive capsule defining an encapsulation space in which to hold the matrix 12 in which the semiconductor nanoparticle phosphors 11 are dispersed. The matrix 12 whose rim is covered with the encapsulation body 13 makes it possible to restrain oxygen and moisture from entering the matrix 12. This makes it possible to restrain the semiconductor nanoparticle phosphors 11 from deteriorating due to oxygen or moisture, and consequently to restrain the semiconductor nanoparticle phosphors 11 from having lower efficiency.

The encapsulation body 13 has a thickness (film thickness) L and an inner diameter R which have therebetween a ratio (L/R) of not more than 1. The encapsulation body 13 has a thickness L of preferably not less than 0.5 nm and not more than 10 μm. The encapsulation body 13 has a thickness L of more preferably not less than 0.5 nm and not more than 5 μm. Note that a film which forms the encapsulation body 13 can include a plurality of layers. In this case, the encapsulation body 13 has a thickness L which is a sum of thicknesses of the plurality of layers.

The encapsulation body 13 which thus has a smaller thickness L allows more semiconductor nanoparticle phosphors 11 to be encapsulated in the encapsulation body 13. Thus, the semiconductor nanoparticle phosphors 11 can absorb more excitation light. This makes it possible for a smaller total weight of the phosphor elements 10 which are being sealed in the sealing material 2 to obtain a desired chromaticity. The thickness of the encapsulation body 13 can be measured with use of a scanning electron microscope or a transmissive electron microscope.

The weight of the phosphor elements 10 which are sealed in the sealing material 2 is defined as not more than 0.8 g with respect to 1 g of the sealing material 2. The reason why the weight of the phosphor elements 10 is thus defined is that an upper limit of the weight of the phosphor elements 10 which allow the wavelength conversion member 1 to be stably produced is 0.8 g with respect to 1 g of the sealing material 2. The phosphor elements 10 whose weight is more than 0.8 g causes clogging in a nozzle from which to eject a mixture of the sealing material 2 and the phosphor elements 10. This causes the mixture to be less handleable, so that the wavelength conversion member 1 cannot be stably mass-produced.

In order to achieve the wavelength conversion member 1 which emits fluorescence having a desired chromaticity, it is necessary to seal, with the sealing material 2, the semiconductor nanoparticle phosphors 11 whose amount corresponds to that chromaticity. The encapsulation body 13 which has a larger thickness causes a smaller amount of the semiconductor nanoparticle phosphors 11 to be encapsulated in the encapsulation body 13. This results in a reduction in amount of the semiconductor nanoparticle phosphors 11 per phosphor element 10, and, conversely, an increase in amount of the encapsulation body 13 per phosphor element 10.

As described earlier, an upper limit of a ratio of the phosphor elements 10 to the sealing material 2, which ratio allows the wavelength conversion member 1 to be stably produced, is determined. A reduction in amount of the semiconductor nanoparticle phosphors 11 per phosphor element 10 makes it difficult to seal the semiconductor nanoparticle phosphors 11 whose amount corresponds to a desired chromaticity.

It is thus preferable to increase a ratio of the amount of the semiconductor nanoparticle phosphors 11 to the weight of the encapsulation body 13 by causing the encapsulation body 13 to have a smaller thickness as described earlier. This makes it easy to achieve the wavelength conversion member 1 which emits fluorescence having a desired chromaticity.

The encapsulation body 13 can be made of any material that is light-transmissive and blocks oxygen and moisture. Such a material is exemplified by, but not particularly limited to, an inorganic material and a polymer material. The inorganic material is highly excellent in blocking of oxygen and moisture. The inorganic material can be, for example, silica, a metal oxide, or a metal nitride.

The encapsulation body 13 which is made of the polymer material, which has flexibility, allows the semiconductor nanoparticle phosphors 11 to be more resistant to shock. Examples of the polymer material include an acrylate polymer, an epoxide, a polyamide, a polyimide, a polyester, a polycarbonate, a polythioether, a polyacrylonitrile, a polydiene, a polystyrene polybutadiene copolymer, parylene, a silica-acrylate hybrid, a polyetheretherketone, a polyvinylidene fluoride, a polyvinylidene chloride, polydivinylbenzene, polyethylene, polypropylene, polyethylene terephthalate, polyisobutylene, polyisoprene, a cellulose derivative, and polytetrafluoroethylene.

(Production Method)

The semiconductor nanoparticle phosphors 11 can be produced by any method that is not particularly limited. The semiconductor nanoparticle phosphors 11 are preferably produced by a chemical synthesis method because the chemical synthesis method is simple and low in cost. According to the chemical synthesis method, an intended product can be obtained by (i) dispersing, in a medium, a plurality of starting materials containing constituent elements of the product and (ii) reacting the plurality of starting materials. Examples of such a chemical synthesis method include a sol-gel method (colloidal method), a hot soap method, a reverse micelle method, a solvothermal method, a molecular precursor method, a hydrothermal synthesis method, and a flux method.

The phosphor elements 10 can also be produced by any method that is not particularly limited. The phosphor elements 10 can be produced by, for example, a method described below.

According to the method, the matrix 12 in which one or more kinds of semiconductor nanoparticle phosphors 11 capped with an ionic modifying agent are dispersed is put in a solution containing the material of the encapsulation body 13, and then a resulting solution is subjected to a process for precipitating the material of the encapsulation body. This makes it possible to obtain the phosphor elements 10 in each of which a surface of the matrix 12 is covered with the encapsulation body 13.

In a case where the phosphor elements 10 have a diameter of not more than 30 μm, the matrix 12 in which the semiconductor nanoparticle phosphors 11 are dispersed is emulsified (micronized) by, for example, a homogenizer, and a resulting mixture is put into a solution containing the material of the encapsulation body.

The thickness of the encapsulation body 13 can be controlled by a condition(s) (e.g., a time, a temperature, pH, and/ or a concentration of the material of the encapsulation body) under which to carry out the process for precipitating the material of the encapsulation body. The thickness L of the encapsulation body 13 can be made smaller by carrying out an adjustment such as an increase in rotation speed of a homogenizer. Alternatively, in a case where the encapsulation body 13 is formed by (i) mixing a first aqueous phase (W1 phase), an n-hexane phase (O phase), and a second aqueous phase (W2 phase) and (ii) emulsifying a resulting mixture, the thickness L of the encapsulation body 13 can be made smaller by reducing a ratio between the W1 phase and the O phase.

The W1 phase is, for example, an aqueous phase in which a 30% aqueous sodium silicate solution and a polymethylmethacrylate aqueous solution are adjusted to 0.42 g/ml and 0.14 g/ml, respectively. The O phase is, for example, an n-hexane phase in which Tween80 (polyoxyethylene sorbitan monooleate) and Span80 (sorbitan monooleate) are adjusted to 0.014 g/ml and 0.007 g/ml, respectively. The W2 phase is, for example, an aqueous phase in which ammonium hydrogencarbonate is adjusted to 0.16 g/ml.

The encapsulation body 13 can be formed by (i) adding the W1 phase to the O phase, (ii) preparing a W1/O phase by emulsifying a mixture of the W1 phase and the O phase with use of a homogenizer at a rotation speed of 8000 rpm, and (iii) immediately adding the W1/O phase thus prepared to the W2 phase and stirring a resulting mixture with a magnetic stirrer at 35° C. for 2 hours.

According to the above-described production method, an ionic liquid contained in the matrix 12 maintains its liquid state. In a case where a resin containing a structural unit derived from the ionic liquid is formed by condensing, curing, and resinifying (solidifying) the ionic liquid, the matrix 12 contains a resin containing a structural unit derived from the ionic liquid.

### Embodiment 2

A further embodiment of the present disclosure is described below. Note that, for convenience, members having functions identical to those of the respective members described in Embodiment 1 are given respective identical reference signs, and a description of those members is not repeated here.

FIG. 3 is a perspective view illustrating a configuration of a wavelength conversion member 1A in accordance with Embodiment 2. As illustrated in FIG. 3, the wavelength conversion member 1A includes phosphor elements 10, phosphor elements 20, and a sealing material 2 in which to seal the phosphor elements 10 and the phosphor elements 20.

The phosphor elements 20 each include a semiconductor nanoparticle phosphor 11 which emits fluorescence having a wavelength different from a wavelength of fluorescence emitted by a semiconductor nanoparticle phosphor 11 which is included in each of the phosphor elements 10. For example, a phosphor element 10 can include a red semiconductor nanoparticle phosphor 11, and a phosphor element 20 can include a green semiconductor nanoparticle phosphor 11. By combining the phosphor element 10 and the phosphor 20 which thus emit fluorescences having respective different wavelengths, it is possible to achieve the wavelength conversion member 1A which emits fluorescence having a desired chromaticity.

### Embodiment 3

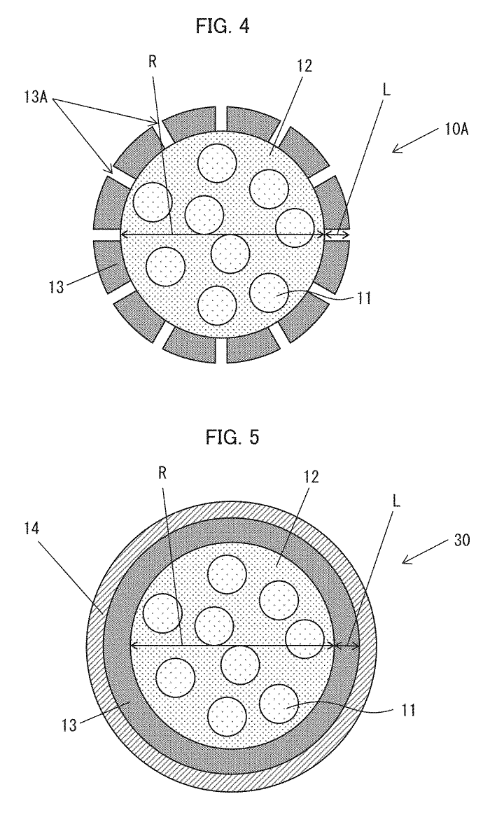

A further embodiment of the present disclosure is described below. FIG. 4 is a cross-sectional view illustrating a configuration of a phosphor element 10A in accordance with Embodiment 3. As illustrated in FIG. 4, fine pores 13A each of which is through from a wall surface to an internal space of an encapsulation body 13 can be provided in the wall surface. The fine pores 13A have a diameter of, for example, not less than 20 nm and not more than 10 μm.

The encapsulation body 13, which has the fine pores 13A, makes it possible to produce the phosphor element 10A, after producing the encapsulation body 13, by injecting, into the encapsulation body 13 produced, a matrix 12 in which semiconductor nanoparticle phosphors 11 are dispersed. The fine pores 13A which have a diameter of not less than 20 nm and not more than 10 μm allow the matrix 12 in which the semiconductor nanoparticle phosphors 11 are dispersed to be efficiently injected into the encapsulation body 13.

### Embodiment 4

A further embodiment of the present disclosure is described below. FIG. 5 is a cross-sectional view illustrating a configuration of a phosphor element 30 in accordance with Embodiment 4. As illustrated in FIG. 5, the phosphor element 30 has a protective substrate 14 on its outermost side. In Embodiment 4, an encapsulation body 13 may have fine pores 13A.

The protective substrate 14 is made of a material which is not limited to any particular material. Examples of at least one of main components of the protective substrate 14 include SiO₂, Al₂O₃, ZnO, In₂O₃, SnO₂, TiO₂, a silicone resin, and an epoxy resin.

The phosphor element 30, which is provided with the protective substrate 14, can be highly chemically stable. Furthermore, in a case where the encapsulation body 13 is provided with the fine pores 13A, the phosphor element 30 which is provided with the protective substrate 14 makes it possible to physically prevent leakage of an ionic liquid from the fine pores 13A, so that handleability of the phosphor element 30 is improved.

### Embodiment 5

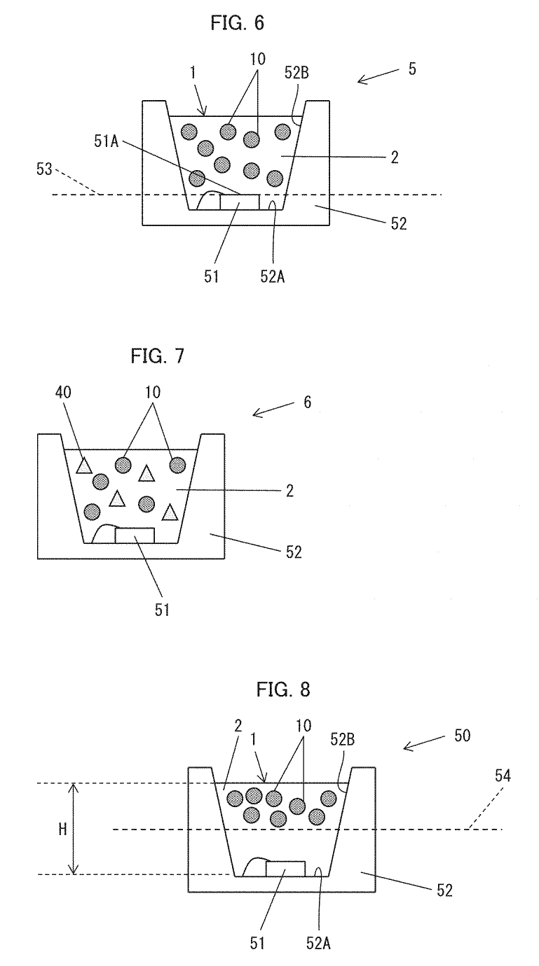

A further embodiment of the present disclosure is described below. FIG. 6 is a cross-sectional view illustrating a configuration of a Light Emitting Diode (LED) package 5 (light emitting device). As illustrated in FIG. 6, the LED package 5 includes an LED 51, a reflector 52, a sealing material 2, and phosphor elements 10. According to the LED package 5, the phosphor elements 10 which are dispersed in the sealing material 2 are directly injected into and sealed in a recessed part 52B of the reflector 52.

The reflector 52 is a member which reflects fluorescence emitted by the phosphor elements 10 (and a part of excitation light emitted by the LED 51), and an inner surface of the recessed part 52B functions as a reflector. The LED 51 is provided on a bottom surface 52A of the recessed part 52B.

The LED 51 is an excitation light source which emits excitation light for exciting a semiconductor nanoparticle phosphor 11 included in each of the phosphor elements 10. The LED 51 does not need to be provided on the bottom surface 52A of the reflector 52. Alternatively, the LED 51 can be provided in a vicinity of the bottom surface 52A of the reflector 52 and on a side surface of the recess 52B. Such a vicinity of the bottom surface 52A is referred to as a bottom part of the reflector 52. The excitation light source can be replaced with another type of light source, such as a semiconductor laser.

The phosphor elements 10 are preferably unevenly distributed on a fluorescence exit side (a side from which fluorescence exits) in a wavelength conversion member 1. More specifically, the phosphor elements 10 are located closer to the fluorescence exit side than an upper surface 51A of the LED 51 in the wavelength conversion member 1. The upper surface 51A is a first surface of the LED 51 which first surface (i) faces away from a second surface of the LED 51 which second surface is in contact with the bottom surface 52A and (ii) is located closer to the fluorescence exit side. FIG. 6 illustrates a plane 53 which is parallel to the bottom surface 52A and includes the upper surface 51A. All the phosphor elements 10 are preferably located closer to the fluorescence exit side than the plane 53. Note, however, that a light emitting device in which an extremely small amount of phosphor elements 10 are inevitably present closer to the bottom surface 52A side than the plane 53 is also included in the technical scope of the present disclosure.

Since the LED 51 generates heat while emitting light, no phosphor element 10 is preferably provided around the LED 51. The phosphor elements 10 which are provided as illustrated in FIG. 6 make it possible to restrain a reduction, caused by heat generated by the LED 51, in quantum efficiency of the semiconductor nanoparticle phosphor 11.

Since the phosphor elements 10 can be handled as in the case of conventional phosphors, the LED package 5 can be produced by a process similar to a process by which to produce an LED package including the conventional phosphors.

The LED package 5 can be produced by, for example, a method described below. According to the method, first, the LED 51 is provided on the bottom surface 52A of the reflector 52. Then, only the sealing material 2 (a first sealing material) is injected into the recessed part 52B of the reflector 52 (a first injection step). During this step, the sealing material 2 is injected sufficiently enough for the upper surface 51A of the LED 51 to be covered with the sealing material 2 injected. Thereafter, the sealing material 2 (a second sealing material) in which the phosphor elements 10 are dispersed is further injected (a second injection step), and the sealing material 2 is subjected to a curing process, so that the wavelength conversion member 1 is completed.

FIG. 7 is a cross-sectional view illustrating a configuration of an LED package 6 including phosphor elements 10 and conventional phosphors 40. As illustrated in FIG. 7, the phosphor elements 10 and the conventional phosphors 40 can be sealed together in a sealing material 2. Since the phosphor elements 10 can be handled as in the case of the conventional phosphors 40, the LED package 6 which has desired emission colors can be produced, by a process similar to a conventional process, by mixing the phosphor elements 10 and the phosphors 40 together.

A conventional phosphor 40 can be, for example, an inorganic phosphor, an organic dye, a rare-earth activated oxynitride phosphor, a CaAlSiN₃ red phosphor, or a YAG:Ce yellow phosphor.

### Embodiment 6

A further embodiment of the present disclosure is described below.

FIG. 8 is a cross-sectional view illustrating a configuration of an LED package 50 (light emitting device) in accordance with Embodiment 6. In FIG. 8, a distance between a bottom surface 52A and the fluorescence exit side surface of a sealing material 2 is denoted by a reference sign H. This distance is referred to as a height H of a wavelength conversion member 1. A plane parallel to the bottom surface 52A and located at a height which is half the height H is denoted by a reference sign 54.

According to the LED package 50, all phosphor elements 10 are unevenly located closer to the fluorescence exit side than the plane 54 in the wavelength conversion member 1. In other words, the phosphor elements 10 are held in a half region of the sealing material 2 which half region is located on the fluorescence exit side. Note, however, that a light emitting device in which an extremely small amount of phosphor elements 10 are inevitably present closer to the bottom surface 52A side than the plane 54 is also included in the technical scope of the present disclosure. That is, according to the LED package 50, substantially all the phosphor elements 10 are located closer to the fluorescence exit side than the plane 54 in the wavelength conversion member 1.

According to the LED package 50, the phosphor elements 10 are at a distance, from the bottom surface 52A, of at least half the height H. According to the LED package 50, the phosphor elements 10 are further away from an LED 51 than the phosphor elements 10 of the LED package 5. Thus, the LED package 50 makes it possible to more effectively restrain a semiconductor nanoparticle phosphor 11 from deteriorating due to heat generated by the LED 51.

(Production Method)

The LED package 50 can be produced by, for example, a method described below. According to the method, first, the LED 51 is provided on the bottom surface 52A of a reflector 52. Then, only the sealing material 2 (a first sealing material) is injected into a recessed part 52B of the reflector 52 (a first injection step). During this step, the sealing material 2 is injected so that an upper surface of the sealing material 2 injected is located closer to the fluorescence exit side than a plane located at a height which is half the height H. Thereafter, the sealing material 2 (a second sealing material) in which the phosphor elements 10 are dispersed is further injected (a second injection step), and the sealing material 2 is subjected to a curing process, so that the wavelength conversion member 1 is completed.

### Embodiment 7

A further embodiment of the present disclosure is described below.

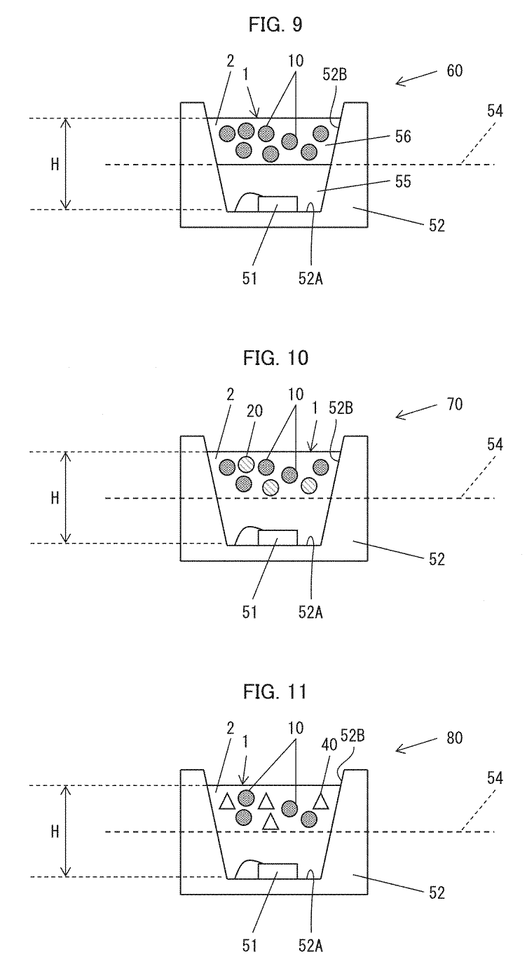

FIG. 9 is a cross-sectional view illustrating a configuration of an LED package 60 in accordance with Embodiment 7. As illustrated in FIG. 9, the LED package 60 includes (i) a first layer 55 formed by sealing an LED 51 with a sealing material 2 which includes no phosphor element 10 and (ii) a second layer 56 obtained by sealing phosphor elements 10 with the sealing material 2. The second layer 56 is located closer to the fluorescence exit side than the first layer 55.

FIG. 9 illustrates a plane 54 located at a height which is half a height H. A boundary surface between the first layer and the second layer 56 is located closer to the fluorescence exit side than the plane 54. That is, the first layer 55 has a height, as measured from a bottom surface 52A, of not less than half the height H, which is a total of a height of the first layer 55 and a height of the second layer 56.

As described above, according to the LED package 60, the phosphor elements 10 are at a distance, from the bottom surface 52A, of at least half the height H. According to the LED package 60, the phosphor elements 10 are further away from the LED 51 than the phosphor elements 10 of the LED package 5. Thus, the LED package 60 makes it possible to more effectively restrain a semiconductor nanoparticle phosphor 11 from deteriorating due to heat generated by the LED 51.

(Production Method)

The LED package 60 can be produced by, for example, a method described below. According to the method, first, the LED 51 is provided on the bottom surface 52A of a reflector 52. Then, only the sealing material 2 is injected into a recessed part 52B of the reflector 52 (a first injection step). During this step, the sealing material 2 is injected so that an upper surface of the sealing material 2 injected is located closer to the fluorescence exit side than a plane located at a height which is half the height H. Then, the sealing material 2 injected is subjected to a curing process, so that the first layer 55 is formed.

Thereafter, the sealing material 2 in which the phosphor elements 10 are dispersed is further injected (a second injection step), and the sealing material 2 is subjected to a curing process, so that the second layer 56 is formed.

The wavelength conversion member 1 which is thus formed in two stages makes it possible, without fail, to form the first layer 55 in which no phosphor element 10 is included in a vicinity of the LED 51, and consequently to provide the phosphor elements 10 at a place away from the LED 51.

### Embodiment 8

A further embodiment of the present disclosure is described below.

FIG. 10 is a cross-sectional view illustrating a configuration of an LED package 70 in accordance with Embodiment 8. As illustrated in FIG. 10, the LED package 70 includes a wavelength conversion member 1 in which phosphor elements 10 and phosphor elements 20 are sealed.

The phosphor elements 20 each include a semiconductor nanoparticle phosphor 11 which emits fluorescence having a wavelength different from a wavelength of fluorescence emitted by a semiconductor nanoparticle phosphor 11 which is included in each of the phosphor elements 10. For example, a phosphor element 10 can include a semiconductor nanoparticle phosphor 11 which emits red fluorescence, and a phosphor element 20 can include a semiconductor nanoparticle phosphor 11 which emits green fluorescence. By combining the phosphor element 10 and the phosphor 20 which thus emit fluorescences having respective different wavelengths, it is possible to achieve the wavelength conversion member 1 which emits fluorescence having a desired chromaticity.

According to the LED package 70, both the phosphor element 10 and the phosphor element 20 are located closer to the fluorescence exit side than a plane 54. This makes it possible to restrain the semiconductor nanoparticle phosphor 11 which is included in each of the phosphor element 10 and the phosphor element 20 from deteriorating due to heat generated by an LED 51.

Note that the phosphor element 10 and the phosphor element 20 can be combined in each of the LED package 5 and the LED package 60.

### Embodiment 9

A further embodiment of the present disclosure is described below.

FIG. 11 is a cross-sectional view illustrating a configuration of an LED package 80 in accordance with Embodiment 9. As illustrated in FIG. 11, the LED package 80 includes a wavelength conversion member 1 in which phosphor elements 10 and conventional phosphors 40 are sealed.

Since the phosphor elements 10 can be handled as in the case of the conventional phosphors 40, the LED package 80 which has desired emission colors can be produced, by a process similar to a conventional process, by mixing the phosphor elements 10 and the phosphors 40 together. A conventional phosphor 40 can be, for example, an inorganic phosphor, an organic dye, a rare-earth activated oxynitride phosphor, a CaAlSiN₃ red phosphor, or a YAG:Ce yellow phosphor.

According to the LED package 80, both a phosphor element 10 and the phosphor 40 are located closer to the fluorescence exit side than a plane 54. This makes it possible to restrain (i) a semiconductor nanoparticle phosphor 11 included in the phosphor element 10 and (ii) the phosphor 40 from deteriorating due to heat generated by an LED 51.

Note that the phosphor element 10 and the conventional phosphor 40 can be combined in each of the LED package 5 and the LED package 60.

### EXAMPLE 1

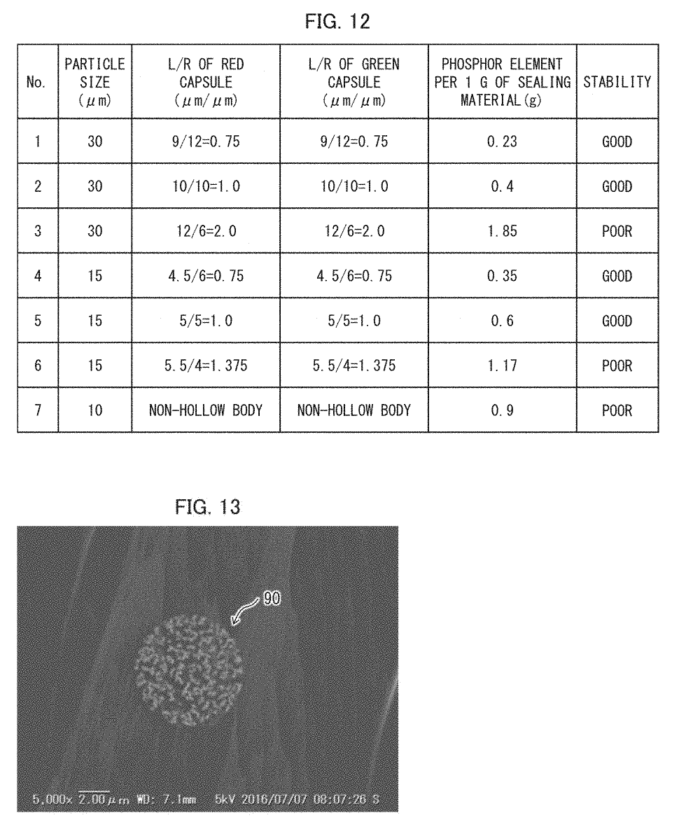

An example of the present disclosure is described below. FIG. 12 shows test results obtained in Example 1. In Example 1, phosphor elements 10 were produced by injecting a mixture of red semiconductor nanoparticle phosphors 11 and a matrix 12 into a plurality of types of encapsulation bodies 13 which differed in ratio L/R between a thickness L and an inner diameter R of an encapsulation body 13. These phosphor elements 10 are referred to as red capsules.

Similarly, phosphor elements 10 were produced by injecting a mixture of green semiconductor nanoparticle phosphors 11 and a matrix 12 into a plurality of types of encapsulation bodies 13. These phosphor elements 10 are referred to as green capsules. For Test Nos. 1 to 3 shown in FIG. 12, the red capsules and the green capsules have a particle size (R+2L) (median diameter) of approximately 30 pm. For Test Nos. 4 to 6, the red capsules and the green capsules have a particle size of approximately 15 μm.

These red capsules and green capsules were used to produce white LEDs having a chromaticity (0.2874, 0.2826). A column (“PHOSPHOR ELEMENT PER 1 G OF SEALING MATERIAL”) of a table of FIG. 12 shows how many grams of red capsules and green capsules were used with respect to 1 g of the sealing material 2. This column shows a total of an amount of red capsules used and an amount of green capsules used. It is shown that a smaller ratio L/ R requires a smaller amount of red capsules and a smaller amount of green capsules.

As shown in Nos. 1, 2, 4, and 5 of FIG. 12, an L/R of not more than 1 allowed an amount of “PHOSPHOR ELEMENT PER 1 G OF SEALING MATERIAL” to be not more than 0.6 g. In this case, production of white LEDs was highly stable (GOOD).

Meanwhile, as shown in Nos. 3 and 6 of FIG. 12, an L/R of more than 1 caused an amount of “PHOSPHOR ELEMENT PER 1 G OF SEALING MATERIAL” to be not less than 1 g. In this case, production of white LEDs was unstable (POOR).

FIG. 13 is an electron micrograph showing a cross section of an encapsulation body 90 which is spherical and has fine pores each extending from a surface to an inside of the encapsulation body. As shown in FIG. 13, the encapsulation body 90 is a non-hollow (solid) body having a diameter of 10 μm. A phosphor element was produced by injecting a mixture of (i) red semiconductor nanoparticle phosphors 11 and green semiconductor nanoparticle phosphors 11 and (ii) a matrix 12 into such an encapsulation body 90 (No. 7). In this case, an amount of “PHOSPHOR ELEMENT PER 1 G OF SEALING MATERIAL” was 0.9 g. This resulted in unstable production of white LEDs (POOR).

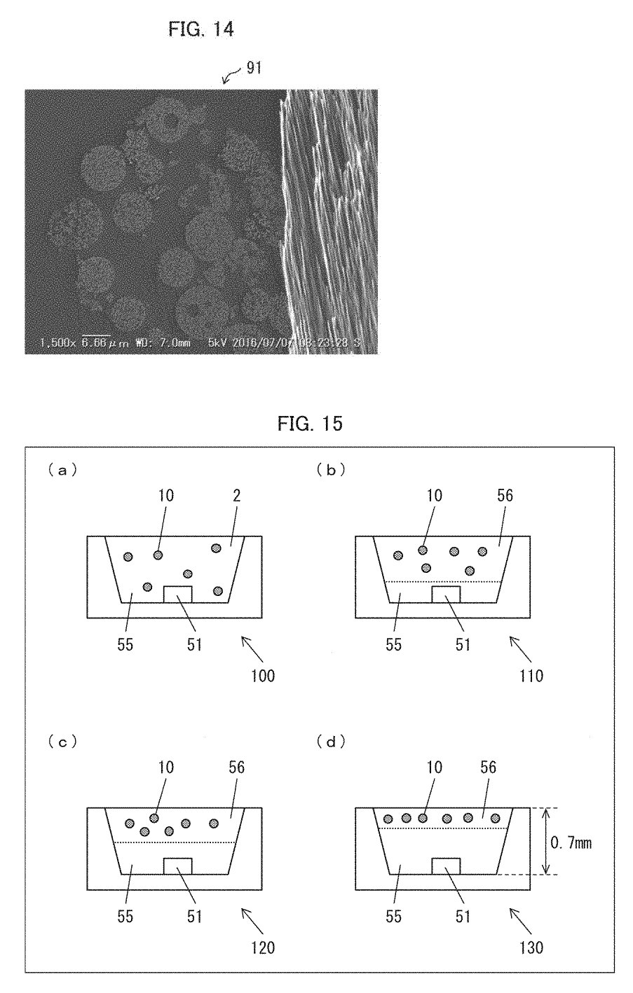

FIG. 14 is an electron micrograph showing a cross section of an encapsulation body 91 whose L/R is more than 1. The encapsulation body 91 shown in FIG. 14 has a median of approximately 10 μm to 20 μm. A phosphor element was produced by injecting a mixture of (i) red semiconductor nanoparticle phosphors 11 and green semiconductor nanoparticle phosphors 11 and (ii) a matrix 12 into such an encapsulation body 91. In this case, an amount of “PHOSPHOR ELEMENT PER 1 G OF SEALING MATERIAL” was 0.84 g. This made it impossible to stably produce white LEDs.

The above results reveal (i) that a ratio (L/R) between the thickness L and the inner diameter R of the encapsulation body 13 was preferably not more than 1 and (ii) that an amount of the “PHOSPHOR ELEMENT PER 1 G OF SEALING MATERIAL” was preferably not more than 0.8 g.

### EXAMPLE 2

A further example of the present disclosure is described below.

FIG. 15 has cross-sectional views illustrating a respective plurality of types of LED packages used in Example 2. In Example 2, an LED package 100, an LED package 110, an LED package 120, and an LED package 130 which are illustrated in respective (a) through (d) of FIG. 15 were used to determine a maintenance ratio of a quantum yield (QY) of semiconductor nanoparticle phosphors 11 contained in each of phosphor elements 10 which are encapsulated in each of these LED packages.

The LED package 100 illustrated in (a) of FIG. 15 is a conventional LED package in which phosphor elements 10 are present around an LED 51. According to the LED package 110 illustrated in (b) of FIG. 15, a first layer 55 and a second layer 56 have respective heights which have therebetween a ratio of 30:70. According to the LED package 120 illustrated in (c) of FIG. 15, the first layer 55 and the second layer 56 have respective heights which have therebetween a ratio of 50:50. According to the LED package 130 illustrated in (d) of FIG. 15, the first layer 55 and the second layer 56 have respective heights which have therebetween a ratio of 80:20. Note that a total of the height of the first layer 55 and the height of the second layer 56 is 0.7 mm.

These LED packages 100, 110, 120, and 130 were caused to continuously illuminate so that a change in quantum yield of the semiconductor nanoparticle phosphors 11 contained in each of the phosphor elements 10 was examined. An LED 51 of each of the LED packages has an output of 30 mW, and the LED 51 emits light having a wavelength of 45 nm.

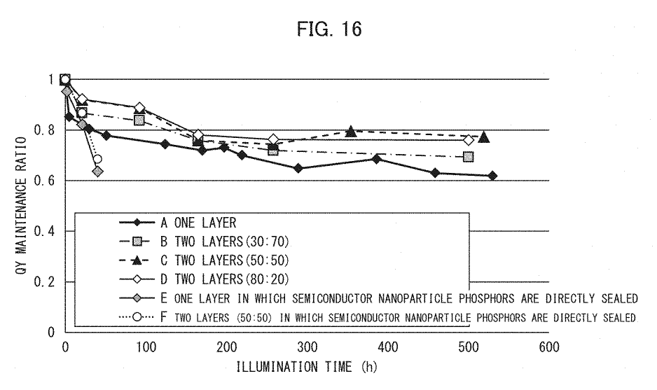

In FIG. 16, line graphs A, B, C, and D show respective results of a test carried for the LED packages 100, 110, 120, and 130 which were caused to illuminate. Line graphs E and F show respective test results each obtained in a case where the semiconductor nanoparticle phosphors 11 are directly sealed in a sealing material 2 without being encapsulated in a sealing body 13. The line graph E shows a result obtained in a case where an LED package includes only one layer (corresponding to (a) of FIG. 15), and the line graph F shows a result obtained in a case where an LED package includes two layers (corresponding to (c) of FIG. 15).

As shown in FIG. 16, the phosphor elements 10 which were kept away from the LED 51 further restrain a reduction in quantum yield. As shown by the line graphs C and D, it was revealed that a reduction in quantum yield of the semiconductor nanoparticle phosphors 11 can be more reliably restrained by keeping the phosphor elements 10 at a distance, from a bottom surface 52A, of not less than half a height H of a wavelength conversion member 1.

In general, a time for which a quantum yield decreases to 70% of an initial quantum yield is regarded as a life of a light emitting device. A light emitting device which has a quantum yield maintenance ratio, obtained after the light emitting device illuminates for not less than 1000 hours, of not less than 0.7 less varies in brightness and thus can be practically usable. An LED package which meets the above criterion (i.e., quantum yield maintenance ratio) can be easily achieved by keeping the phosphor elements 10 at a distance, from the bottom surface 52A, of not less than half the height H of the wavelength conversion member 1.

(Additional Remarks)

The present disclosure is not limited to the embodiments, but can be altered by a skilled person in the art within the scope of the claims. The present disclosure also encompasses, in its technical scope, any embodiment derived by combining technical means disclosed in different embodiments. Further, it is possible to form a new technical feature by combining the technical means disclosed in the respective embodiments.

### REFERENCE SIGNS LIST

1, 1A wavelength conversion member

2 Sealing material

5, 6, 50, 60, 70, 80 LED package (light emitting device)

12 Matrix

10, 10A, 20, 30 Phosphor element

11 Semiconductor nanoparticle phosphor

13 Encapsulation body

13A Fine pore

14 Protective substrate

40 Phosphor

51 LED

51A Upper surface

52 Reflector

52A Bottom surface

52B Recessed part

1. A wavelength conversion member comprising:
a phosphor element; and
a sealing material in which to seal the phosphor element,
the phosphor element including:
an encapsulation body which defines an encapsulation space and is hollow and light-transmissive;
a matrix which is encapsulated in the encapsulation body and contains (i) an ionic liquid or (ii) a resin having a structural unit derived from the ionic liquid; and
semiconductor nanoparticle phosphors dispersed in the matrix,
the encapsulation body having a thickness L and an inner diameter R which have therebetween a ratio L/ R of not more than 1,
the phosphor element having a particle size of not less than 1 μm and not more than 30 μm, and the phosphor element being sealed in the wavelength conversion member while having a weight of not more than 0.8 g with respect to 1 g of the sealing material.

2. The wavelength conversion member as set forth in claim 1, wherein the thickness L of the encapsulation body is not less than 0.5 nm and not more than 10 μm.

3. The wavelength conversion member as set forth in claim 1, wherein the matrix contains the ionic liquid which has no polymerizable functional group.

4. The wavelength conversion member as set forth in claim 1, wherein the matrix contains the ionic liquid which has a polymerizable functional group.

5. A light emitting device comprising a wavelength conversion member recited in claim 1.
